(19) United States
(12) Patent Application Publication
(10) Pub. No.: US 2008/0060698 A1
(43) Pub. Date: Mar. 13, 2008

(54) Electrolyte Composition And Photoelectric Conversion Element Utilizing The Same

(76) Inventors: Masayoshi Watanabe, Yokohama-shi (JP); Ryuji Kawano, Yokohama-shi (JP); Chizuru Matsuyama, Yokohama-shi (JP); Hiroshi Matsui, Tokyo (JP); Nobuo Tanabe, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/571,054

(22) PCT Filed: Sep. 6, 2004
(86) PCT No.: PCT/JP04/13253

§ 371 Date: May 14, 2007

(30) Foreign Application Priority Data
Sep. 8, 2003 (JP) 2003-315955

(51) Int. Cl. H01G 9/035; H01L 31/0264; H01L 31/04

(52) U.S. Cl. 136/265; 136/252; 252/62.2

(57) ABSTRACT

An electrolyte composition containing an ionic liquid having dicyanoamide anions as anions. Examples of cations of the ionic liquid, may include, for example, cations having a quaternized nitrogen atom. This electrolyte composition may contain a halogen-based oxidized/reduced pair. This electrolyte composition is used as an electrolyte of a photoelectric conversion element.

Priority is claimed on Japanese Patent Application No. 2003-315955, filed Sep. 8, 2003, the content of which is incorporated herein by reference.

### TECHNICAL FIELD

The present invention relates to an electrolyte composition and a photoelectric conversion element utilizing the same.

### BACKGROUND ART

Dye-sensitized solar cells which were developed by Graetzel et al. in Switzerland have advantages, such as higher photoelectric conversion efficiency and lower cost, and are attracting attention as new types of solar cells (see, Japanese Patent No. 2664194, and Japanese Unexamined Patent Application, First Publications Nos. 2001-160427, 2001-230434, and 2002-184478, for example).

The typical structure of dye-sensitized solar cells comprises a transparent conductive electrode substrate, a working electrode formed on the electrode substrate which has a porous film made of oxide semiconductor fine particles (nanoparticles), such as titanium dioxide, and sensitized with a photo-sensitizing dye, a counter electrode provided opposing the working electrode, and an electrolyte containing an oxidized/reduced pair filled between the working electrode and the counter electrode.

Such a dye-sensitized solar cell functions as a photoelectric conversion element that converts light energy into electricity when the oxide semiconductor fine particles are sensitized by the photo-sensitizing dye that absorbs incident light, such as sunlight, thereby generating an electromotive force between the working electrode and the counter electrode.

As the electrolyte, an electrolyte solution is typically used in which an oxidized/reduced pair, such as I⁻/I₃⁻, is dissolved in a typical organic solvent, such as acetonitrile. Other well-known electrolytes include one using a nonvolatile ionic liquid, one in which the liquid electrolyte is made into a gel using an appropriate gelling agent to be quasi-solidified, and one using a solid semiconductor, such as a p-type semiconductor.

However, when an organic solvent, such as acetonitrile or the like, is used for preparation of the electrolyte solution, a sufficient conductivity may not be ensured across the electrodes if the amount of the electrolyte solution is reduced due to volatilization of this organic solvent, resulting in a reduction in the photoelectric conversion characteristic. Accordingly, it may difficult to ensure a sufficient life time if such a solar cell is used, particularly outside.

Another issue may arise when a nonvolatile ionic liquid is used as the electrolyte although such an electrolyte solution can prevent volatilization of the solution. Since nonvolatile ionic liquids have a high viscosity, the rate of charge transfer in the electrolyte is lower and thus the output may be decreased when compared with a case in which a volatile electrolyte solution is used. Although some efforts have been made in order to increase the carrier concentration for achieving an improvement in the output current, they have not led to any significant fruitful results. Furthermore, the issue of a decreased voltage is generally to be rectified.

### DISCLOSURE OF INVENTION

The present invention was conceived in light of the above-described circumstances, and an object thereof is to provide an electrolyte composition that provides excellent performance and a photoelectric conversion element utilizing the same.

In order to solve the above problem, the present invention provides an electrolyte composition comprising an ionic liquid including dicyanoamide anions as anions. Examples of cations of the ionic liquid may include, for example, cations having a quaternized nitrogen atom.

The electrolyte composition according to the present invention may include a halogen-based oxidized/reduced pair. Preferred applications of the electrolyte composition according to the present invention may include, for example, an electrolyte for a photoelectric conversion element.

Furthermore, the present invention provides a photoelectric conversion element comprising the above-described electrolyte composition as an electrolyte. Examples of such a photoelectric conversion element may include, for example, a dye sensitizing solar cell.

Since the electrolyte composition according to the present invention has excellent characteristics, it may be used for various applications as an electrolyte. When the electrolyte composition according to the present invention is used as an electrolyte for a photoelectric conversion element, it is possible to achieve a good photoelectric conversion characteristic since it can realize both a high current characteristic and a high voltage characteristic.

### BRIEF DESCRIPTION OF THE DRAWINGS

FIG. 1 is a cross-sectional view illustrating an example of a photoelectric conversion element according to the present invention.

### BEST MODE FOR CARRYING OUT THE INVENTION

Preferred embodiments of the invention will be described with reference to the drawings. However, it should not be construed that the present invention is limited to the below-mentioned embodiments; rather, components of those embodiments, for example, may be combined if necessary.

The present invention will now be described in detail based on preferred embodiments.

The electrolyte composition according to the present invention includes an ionic liquid including dicyanoamide anions as anions.

The ionic liquid is not particularly limited as long as it contains dicyanoamide anions as anions, and room temperature molten salts that are liquid at room temperature may be used. Examples of counter cations for the dicyanoamide anions may include, for example, cations having a quaternized nitrogen atom.

Cations having a quaternized nitrogen atom (hereinafter referred to as “cations having a quaternary nitrogen atom”) are quaternary ammonium (N⁺R¹R²R³R⁴; where R¹ to R⁴ are substituent groups, such as an alkyl group, a cycloalkyl group, an aryl group, an aralkyl group, or the like, and a part or all of the hydrogen atom(s) of the substituent group may be substituted); or cations of a heterocyclic ring-containing nitrogen compound, such as limidazolium, pyridinium, pyrrolidinium, pyrazolidinum, isothiazolidinium, isoxazolidinium, or the like. The cations having a quaternary nitrogen atom may include a substituent group for combining to a quaternized nitrogen atom or a different atom of the ring, such as an alkyl group, a cycloalkyl group, an aryl group, an aralkyl group, or the like, as a substituent group.

Concrete examples of ionic liquids containing dicyanoamide anions are 1-ethyl-3-methylimidazolium-dicyanoamide, N-butylpyridinium-dicyanoamide, N-ethyl-N-methyl pyridinium-dicyanoamide, N-propyl-N-methyl pyridinium-dicyanoamide, N-butyl-N-methyl pyridinium-dicyanoamide, N-hexyl-N-methyl pyridinium-dicyanoamide, N-pentyl-N,N,N-triethyl ammonium-dicyanoamide, N-hexyl-N, N,N-triethyl ammonium-dicyanoamide, N-pentyl-N,N,N-tributyl ammonium-dicyanoamide, or the like.

Methods for synthesizing such an ionic liquid include, for example, a method based on anion exchange of a salt of a cation having a quaternary nitrogen atom using a dicyanoamide metal salt, such as sodium dicyanoamide, silver dicyanoamide, or the like. The synthesis method according to the anion exchange is described in, for example, Green Chemistry, 2002, Vol. 4, 444-448.

Oxidized-reduced pairs (redox pairs) may be added to the electrolyte composition according to the present invention, although they are not an essential component. It is preferable to add an oxidized/reduced pair when the electrolyte composition is used in a dye-sensitized solar cell or the like.

As the oxidized/reduced pair, a halogen-based oxidized/reduced pair made of halide ions, such as iodide ions (I⁻), bromide ions (Br⁻), or chloride ions (Cl⁻), and polyhalide ions, such as Br₃⁻, I₃⁻, I₅⁻, I₇⁻, Cl₂I⁻, ClI₂⁻, Br₂I⁻, BrI₂⁻, is preferably used, although these are not limiting.

Halogen-based oxidized/reduced pairs can be obtained by making halide ions, such as Cl⁻, Br⁻, I⁻, or the like, react with halogen molecules. As the halogen molecules, elemental halogen molecules, such as C1₂, Br₂, I₂, or the like, and/or inter-halogen compounds, such as ClI, BrI, BrCl, or the like, may be used. In more concrete terms, iodine/iodide ions or bromine/bromide ions may be exemplified.

The ratio of the halogen molecule with respect to the halide ion is not particularly limited, and, the molar ratio is more preferably between 0% and 100%. Although the addition of halogen molecules is not essential, it is preferable to add halogen molecules since the halide ions and the polyhalide ion may form an oxidized/reduced pair in the presence of polyhalide ions, which may improve characteristics, such as the photoelectric conversion characteristic.

For the supply source of the halogen ions, a lithium salt, quaternary imidazolium salt, tetrabutylammonium salt, and the like may be used alone or in combination.

The electrolyte composition according to the present invention may be a gel that is made into a gel physically or chemically using an appropriate gelling agent.

Various additives may be added to the electrolyte composition according to the present invention if necessary in an amount in which the properties and characteristics of the electrolyte composition are not interfered with, and such additives may include, for example, organic nitrogen compounds such as 4-tert-butyl pyridine, 2-vinyl pyridine, N-vinyl-2-pyrrolidone, or the like; a lithium salt, a sodium salt, a magnesium salt, an iodide salt, a thiocyanate, water, or the like.

The methods for preparing the electrolyte composition of the present invention from the components described above are not particularly limited, and a method may be employed, for example, in which an electrolyte solution is obtained by adding additives, such as an oxidized/reduced pair, to an ionic liquid and uniformly blending the above-described conductive particles into the electrolyte solution.

The electrolyte composition of the present invention is preferably used as an electrode for photoelectric conversion elements, such as dye-sensitized solar cells, for example. Since an ionic liquid including dicyanoamide anions as the anions has lower viscosity than conventional ionic liquids, it can be expected that it will exhibit effects such as improving the rate of charge transfer in the electrolyte. Furthermore, this electrolyte composition is characteristics in that a dye sensitizing solar cell using the electrolyte composition provides a higher electromotive force (open-circuit voltage) when compared with the case in which an ionic liquid is used.

It is believed that the electrolyte composition may be used for various applications in fields other than photoelectric conversion elements in place of conventional electrolyte solutions or electrolytes.

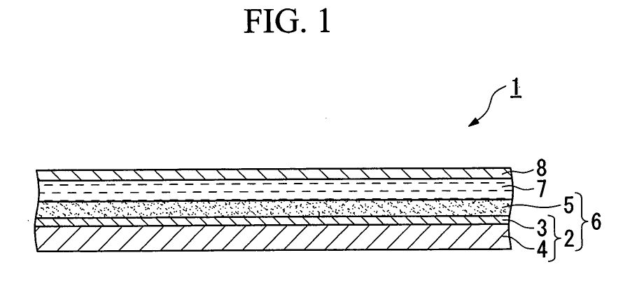

Next, an example of an embodiment of a photoelectric conversion element using the above-described electrolyte composition will be explained. FIG. 1 is a cross-sectional view showing an example of a schematic structure of a dye-sensitized solar cell, as an embodiment of the photoelectric conversion element of the present invention.

This dye-sensitized solar cell 1 includes a transparent electrode substrate 2, a working electrode 6 having an oxide semiconductive porous film 5 formed on the transparent electrode substrate 2 which is made of oxide semiconductive fine particles, such as titanium dioxide, and sensitized with a photo-sensitizing dye, and a counter electrode 8 provided opposing the working electrode 6. An electrolyte layer 7 that is made of the above-described electrolyte composition is provided between the working electrode 6 and the counter electrode 8.

The transparent electrode substrate 2 is made by forming a conductive layer 3 made of a conductive material on a transparent base material 4, such as a glass plate or a plastic sheet.

The transparent base material 4 is preferably made of a material having excellent optical transparent properties when taking its application into consideration. Other than glass, transparent plastic sheets made of polyethylene terephthalate (PET), polyethylene naphthalate (PEN), polycarbonate (PC), polyether sulfone (PES), or the like; a polished plate of a ceramic, such as titanium oxide, alumina, or the like, may be used.

For the conductive layer 3, it is preferable that transparent oxide semiconductors, such as tin-doped indium oxide (ITO), tin oxide (SnO₂), fluorine-doped tin oxide (FTO), or the like, be used either alone or in a mixture of two or more thereof when taking the light transmittance of the transparent electrode substrate 2 into consideration. However, these materials are not limiting, and any suitable material having light transmittance and conductivity appropriate for an intended purpose may be used. Furthermore, in order to improve the current collecting efficiency from the oxide semiconductor porous film 5 or the electrolyte layer 7, a metal wiring layer made of gold, silver, platinum, aluminum, nickel, titanium, or the like, may be used provided that an area ratio of the metal wiring layer is within the range that does not significantly reduce the light transmittance of the transparent electrode substrate 2. When such a metal wiring layer is used, the metal wiring layer may be provided as a grid-like, stripe-like, or comb-like pattern so that light transmits through the transparent electrode substrate 2 as evenly as possible.

The method used to form the conductive layer 3 is not particularly limited, and any known method may be used. Examples thereof include thin film formation methods, such as a sputtering method, or a CVD method, or a spray decomposition method (SPD), or an evaporation method, when the conductive layer 3 is formed from a oxide semiconductor, such as ITO. The conductive layer 3 is formed to a thickness of between about 0.05 μm and 2.0 μm considering the optical transparent properties and the conductivity.

The oxide semiconductor porous film 5 is a porous thin layer with a thickness between about 0.5 and 50 μm containing as a main component oxide semiconductor fine particles that are made of titanium oxide (TiO₂), tin oxide (SnO₂), tungsten oxide (W0₃), zinc oxide (ZnO), and niobium oxide (Nb₂O₅), used either alone or in a combination of two or more materials, and have an average particle diameter between 1 nm to 1000 nm.

The oxide semiconductor porous film 5 can be formed, for example, by employing methods such as a method in which a dispersion solution obtained by dispersing commercially available oxide semiconductor fine particles in a desired dispersion medium is coated, or a colloidal solution that can be prepared using a sol-gel method is coated, after desired additives have been added thereto if these are required, using a known coating method such as a screen printing method, an inkjet printing method, a roll coating method, a doctor blade method, a spin coating method, a spray coating method, or the like. Other methods include: an electrophoretic deposition method in which the electrode substrate 2 is immersed in a colloidal solution and oxide semiconductor fine particles are made to adhere to the electrode substrate 2 by electrophoresis; a method in which a foaming agent is mixed in a colloidal solution or dispersion solution which is then coated and baked so as to form a porous material; and a method in which polymer microbeads are mixed together and coated on, and these polymer microbeads are then removed by thermal treatment or chemical treatment, so as to define spaces and thereby form a porous material.

The sensitizing dye that sensitizes the oxide semiconductor porous film 5 is not particularly limited, and it is possible to use ruthenium complexes or iron complexes containing a ligand having bipyridine structures, terpyridine structures, and the like; metal complexes such as porphyrin and phthalocyanine; as well as organic dyes such as eosin, rhodamine, melocyanine, and coumarin. The dye can be selected according to the application and the material used for the oxide semiconductor porous film.

The counter electrode 8 may be one obtained by forming a thin film made of a conductive oxide semiconductor, such as ITO, FTO, or the like, on a substrate made of a non-conductive material, such as glass, or one obtained by forming an electrode by evaporating or applying a conductive material, such as gold, platinum, a carbon-based material, and the like, on a substrate. Furthermore, the counter electrode 8 may be one obtained by forming a layer of platinum, carbon, or the like, on a thin film of a conductive oxide semiconductor, such as ITO, FTO, or the like.

A method for forming the counter electrode 8 includes, forming a platinum layer by applying chloroplatinate and then performing a heat treatment, for example. Alternatively, a method may be used in which the electrode is formed on a substrate by an evaporation technique or sputtering technique.

The electrolyte composition including an ionic liquid including dicyanoamide anions as anions is filled between the working electrode 6 and the counter electrode 8, thereby the electrolyte layer 7 is formed.

According to the photoelectric conversion element of this embodiment, since the main component of the electrolyte composition is the ionic liquid including dicyanoamide anions as anions, it can achieve both a higher current characteristic and a higher voltage characteristic and therefore provides a better photoelectric conversion characteristic when compared with conventional ionic liquids.

### EXAMPLES

### Synthesis of Ionic Liquid

### 1. Synthesis of 1-ethyl-3-methylimidazolium-dicyanoamide

A conventional method was employed to react 1-methylimidazole react with ethyl bromide to obtain 1ethyl-3-methylimidazolium-bromide. It was purified using recrystallization and then was mixed with sodium dicyanoamide in acetone for performing anion exchange, thereby synthesizing the ionic liquid according to the following formula 1. The resultant 1-ethyl-3-methylimidazolium-dicyanoamide was used for preparing an electrolyte solution after being purified using a silica column.

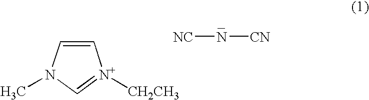

### 2. Synthesis of 1-butylpyridinium-dicyanoamide

A conventional method was used to react pyridine with butyl bromide to obtain 1-butylpyridinium bromide. It was purified using recrystallization and then was mixed with sodium dicyanoamide in acetone for performing anion exchange, thereby synthesizing the ionic liquid according to the following formula 2. The resultant 1-butylpyridinium-dicyanoamide was used for preparing an electrolyte solution after being purified using a silica column.

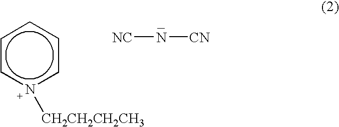

### 3. Synthesis of 1-ethyl-3-methylimidazolium-bistrifluoromethyl sulfonylimide

A conventional method was employed to react 1-methylimidazole react with ethyl bromide to obtain 1-ethyl-3-methylimidazolium-bromide. It was purified using recrystallization and then was mixed with bistrifluoromethyl sulfonylimide-lithium salt in water for performing anion exchange, thereby synthesizing the ionic liquid according to the following formula 3. The resultant 1-ethyl-3-methylimidazolium-bistrifluoromethyl sulfonylimide was used for preparing an electrolyte solution after being sufficiently cleaned using pure water.

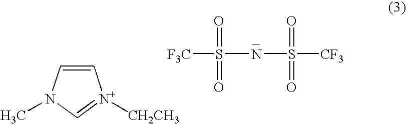

### 4. 1-Hexyl-3-methylimidazolium-iodide

A commercially available 1-hexyl-3-methylimidazolium-iodide according to the following formula 4 purchased and used.

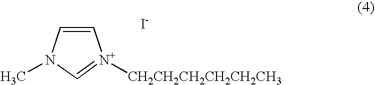

### Preparation of Electrolyte Composition

Electrolyte compositions according to Numbers 1 to 7 were prepared by mixing the ionic liquids, an oxidized/reduced pair, and other optional additives according to the compositions listed in Table 1.

In Table 1, the following abbreviations are used:
EMIm-DCA: 1-ethyl-3-methylimidazolium-dicyanoamide
BP y DCA: 1-butylpyridinium-dicyanoamide
EMIm-TFSI: 1-ethyl-3-methylimidazolium-bistrifluoromethyl sulfonylimide
HMIm-I: 1hexyl-3methylimidazolium-iodide
EMIm-I: 1-ethyl-3methylimidazolium-iodide
TBP: 4-tert-butyl pyridine
LiI: lithium iodide

Furthermore, in the electrolyte composition of Number 2, vinylidene fluoride-propene hexafluoride copolymer was used as the gelling agent.

TABLE 1

| No. | Ionic Liquid | Oxidized / Reduced pair | Additive |
|---|---|---|---|
| 1 | EMIm-DCA | EMIm-I (1.5 M) + I₂ (0.15 M) | TBP + LiI |
| 2 | EMIm-DCA | EMIm-I (1.5 M) + I₂ (0.15 M) | TBP + LiI + gelling |
| | | | agent |
| 3 | BPy-DCA | EMIm-I (1 M) + I₂ (0.1 M) | none |
| 4 | BPy-DCA | EMIm-I (1.5 M) + I₂ (0.15 M) | TBP + LiI |
| 5 | EMIm-TFSI | EMIm-I (1.5 M) + I₂ (0.15 M) | TBP + LiI |
| 6 | EMIm-TFSI | EMIm-I (1.5 M) + I₂ (0.15 M) | none |
| 7 | HMIm-I | HMIm-I + I₂ | TBP + LiI |
| | | (mixed at a ratio of 10:1) | |

### Preparation of Test Cells

A slurry containing titanium oxide nanoparticles of a particle size of between 13 nm to 20 nm was applied to a glass substrate having an FTO film formed thereon, and dried, and then heated and baked at 450° C. for one hour to form an oxide semiconductive porous film. It was then immersed overnight in a dye solution so that the oxide semiconductive porous film became sensitized with the dye to form a photoelectrode. A ruthenium bipyridine complex (an N3 dye) was used as the dye.

Using the above-described dye-sensitized electrode as the working electrode, and a glass substrate having an FTO film formed thereon formed by the sputtering technique was used as the counter electrode opposing this working electrode.

The working electrode and the counter electrode were overlaid each other, and the electrolytic solution was filled between the electrodes to form a dye-sensitized solar cell that was a test cell.

### Evaluation of Test Cells

The photoelectric conversion characteristics of the test cells were evaluated under photoirradiation conditions with an air mass (AM) of 1.5 and an irradiance of 100 cmW². The evaluation results are listed in Table 2. In Table 2, test cells of Numbers 1 to 4 represent working examples employing the electrolyte composition according to the present invention whereas the test cells of Numbers 5 and 7 resent comparative examples employing conventional electrolyte compositions.

TABLE 2

| No. | Photoelectric Conversion Efficiency (%) |
|---|---|
| 1 | 5.5 |
| 2 | 5.4 |
| 3 | 5.5 |
| 4 | 6.1 |
| 5 | 4.5 |
| 6 | 3.2 |
| 7 | 4.3 |

As shown in Table 2, test cells of the working examples (Numbers 1 to 4) provided higher conversion efficiencies than test cells of the comparative examples (Numbers 5 to 7).

From the above comparison results, it is evident that photoelectric conversion elements having better output characteristics may be obtained according to the present invention.

### INDUSTRIAL APPLICABILITY

Since the electrolyte composition according to the present invention has excellent characteristics, it may be used for various applications as an electrolyte.

The photoelectric conversion element according to the present invention exhibits an excellent photoelectric conversion efficiency. Accordingly, a solar cell, such as dye sensitizing solar cell or the like using such a photoelectric conversion element is especially effective.

We claim:

1. An electrolyte composition comprising ionic liquid including dicyanoamide anions as anions.

2. The electrolyte composition according to claim 1, wherein the ionic liquid comprises cations having quaternized nitrogen atom.

3. The electrolyte composition according to claim 1 comprising halogen-based redo pair.

4. The electrolyte composition according to claim 1 as an electrolyte of a photoelectric conversion element.

5. A photoelectric conversion element comprising the electrolyte composition according to claim 1 as an electrolyte.

6. The photoelectric conversion element according to claim 5 being a dye-sensitized solar cell.

7. The electrolyte composition according to claim 2 wherein the cations having quaternized nitrogen atom include quaternary ammonium, or cations of a nitrogen-containing heterocyclic compound.

8. The electrolyte composition according to claim 1 wherein the ionic liquid includes 1-ethyl-3-methylimidazolium dicyanamide, N-butylpyridinium dicyanoamide, N-ethyl-N-methyl pyridinium dicyanamide, N-propyl-N-methyl pyridinium dicyanamide, N-butyl-N-methyl pyridinium dicyanamide, N-hexyl-N-methyl pyridinium dicyanamide, N-pentyl-N,N,N-triethyl ammonium dicyanamide, N-hexyl-N,N,N-triethyl ammonium dicyanamide, and N-pentyl-N,N,N-tributyl ammonium dicyanamide.

9. The electrolyte composition according to claim 8 wherein the ionic liquid is selected from the group consisting of 1-ethyl-3-methylimidazolium dicyanamide and N-butylpyridinium dicyanamide.

10. The electrolyte composition according to claim 3 wherein the halogen-based redox pair includes halide ions and polyhalide ions.

11. The electrolyte composition according to claim 10 wherein the halide tons are selected from the group consisting of iodide ions (I⁻), bromide ions (Br⁻), and chloride ions (Cl⁻).

12. The electrolyte composition according to claim 10 wherein the polyhalide ions are selected from the group consisting of Br₃⁻; I₃⁻; I₅⁻, I₇⁻, Cl₂I⁻, ClI₂⁻; Br₂I⁻, and BrI₂⁻.

13. The electrolyte composition according to claim 3 wherein the halogen-based redox pair includes one which is obtained by mixing iodine/iodide ions or bromine/bromide ions.

14. The electrolyte composition according to claim 3 wherein the halogen-based redox pair is formed reacting halide ions with halogen molecules.

15. The electrolyte composition according to claim 1 further comprising a gelator.

16. The electrolyte composition according to claim 1 further comprising additives which include a organic nitrogen compound, a lithium salt, a sodium salt, a magnesium salt, an iodide salt, a thiocyanate salt, and water.

17. A dye-sensitized solar cell comprising a transparent electrode substrate, a working electrode having an oxide semiconductive porous film formed on the transparent electrode substrate which is made of oxide semiconductive fine particles and having a photo-sensitizing dye absorbed thereon, and a counter electrode provided opposing the working electrode, and an electrolyte layer comprising the electrolyte composition according to claim 1 which is provided between the working electrode and the counter electrode.

18. The dye-sensitized solar cell according to claim 17 wherein the transparent electrode substrate comprises a conductive layer made of a conductive material on a transparent substrate.

19. The dye-sensitized solar cell according to claim 18 wherein the transparent substrate includes glass, a transparent plastic substrate, and a polished plate of a ceramic.

20. The dye-sensitized solar cell according to claim 18 wherein the conductive layer includes a transparent oxide semiconductor selected from the group consisting of tin-doped indium oxide (ITO), tin oxide (SnO₂), fluorine-doped tin oxide (FTO), and mixtures thereof.

21. The dye-sensitized solar cell according to claim 18 wherein the conducive layer has a thickness of between about 0.05 82 m and 2.0 μm.

22. The dye-sensitized solar cell according to claim 17 wherein the oxide: semiconductor porous film is a porous thin layer with a thickness between about 0.5 and 50 μm containing as a main component oxide semiconductor fine particles which include titanium oxide (TiO₂), tin oxide (SnO₂), tungsten oxide (WO₃), zinc oxide (ZnO), niobium oxide (Nb₂O₅), and mixtures thereof, where said oxide semiconductor fine particles have an average particle diameter between 1 nm to 1000 nm.

23. The dye-sensitized solar cell according to claim 17 measuring photoelectric conversion efficiency greater than 4.5%.
